(19) United States
(12) Patent Application Publication
(10) Pub. No.: US 2024/0101896 A1
(43) Pub. Date: Mar. 28, 2024

(54) QUANTUM DOT, AND DISPLAY DEVICE COMPRISING THE QUANTUM DOT

(71) Applicant: Samsung Display Co., Ltd., Yongin-si (KR)

(72) Inventors: Youngsik KIM, Yongin-si (KR); Sungjae KIM, Yongin-si (KR); Seung-Won PARK, Yongin-si (KR); Bitna YOON, Yongin-si (KR); Donghee LEE, Yongin-si (KR); Junehyuk JUNG, Yongin-si (KR)

(21) Appl. No.: 18/362,825

(22) Filed: Jul. 31, 2023

(30) Foreign Application Priority Data
Sep. 27, 2022 (KR) 10-2022-0122447

(51) Int. Cl. C09K 11/70; C09K 11/02; C09K 11/56; C09K 11/88; H10K 59/38

(52) U.S. Cl. CPC C09K 11/70; C09K 11/02; C09K 11/565; C09K 11/883; H10K 59/38

(57) ABSTRACT

A quantum dot includes a core including InP, a first shell around (e.g., surrounding) the core and including ZnTeSe, a second shell around (e.g., surrounding) the first shell and including ZnSe, and a third shell around (e.g., surrounding) the second shell and including ZnS, wherein the ratio of the number of moles of the Te in the first shell to the number of moles of the P in the core is about 0.02 to about 0.90.

### CROSS-REFERENCE TO RELATED APPLICATIONS

This application claims priority to and the benefit of Korean Patent Application No. 10-2022-0122447, filed on Sep. 27, 2022, the entire content of which is hereby incorporated by reference.

### BACKGROUND

Embodiments of the present disclosure relate to a quantum dot, and a display device including the same, and for example, to a quantum dot having a core-shell structure, and a display device including the same.

Various display devices utilized in multimedia apparatuses such as televisions, mobile phones, tablet computers, navigation systems, and/or game consoles are being developed. Such a display device includes a display module having a so-called self-emission type or kind display element which produces a display by utilizing a light-emitting material.

Moreover, display devices may include different types (kinds) of light control layers associated with pixels of the display device in order to improve color reproducibility. The light control layer may be to transmit only light having a certain wavelength range from a light source, or may be to change the wavelength range of light from a light source. Developments of light-emitting elements utilizing quantum dots as light-emitting materials are in progress, and it is desirable or necessary to improve the luminous efficiency and high color characteristics of the light-emitting elements utilizing quantum dots.

### SUMMARY

Aspects of embodiments of the present disclosure are directed toward a quantum dot having excellent or suitable external quantum efficiency.

Aspects of embodiments of the present disclosure are directed toward a display device including a light control layer which has a quantum dot with excellent or suitable external quantum efficiency, and thus having excellent or suitable luminous efficiency.

Additional aspects will be set forth in part in the description which follows and, in part, will be apparent from the description, or may be learned by practice of the presented embodiments of the disclosure.

One or more embodiments of the present disclosure provides a quantum dot including a core including InP, a first shell around (e.g., surrounding) the core and including ZnTeSe, a second shell around (e.g., surrounding) the first shell and including ZnSe, and a third shell around (e.g., surrounding) the second shell and including ZnS, wherein the ratio of the number of moles of the Te in the first shell to the number of moles of the P in the core is about 0.02 to about 0.90.

In one or more embodiments, the first shell may be to absorb light with a center wavelength of about 440 nm to about 460 nm.

In one or more embodiments, the first shell may be a layer most adjacent to the core (e.g., the layer closer to the core than the second shell and the third shell).

In one or more embodiments, a bandgap energy of the first shell may be less than a bandgap energy of the second shell and less than a bandgap energy of the third shell.

In one or more embodiments, the quantum dot may be to emit light with a center wavelength of about 510 nm to about 540 nm.

In one or more embodiments, the quantum dot may have a diameter of about 5 nm to about 7 nm.

In one or more embodiments of the present disclosure, a display device includes a base layer, a display element layer on the base layer and having a plurality of light-emitting elements, and a light control layer having a partitioning pattern on the display element layer, and a first light control part, a second light control part, and a third light control part which are separated by the partitioning pattern, the first light control part having a first quantum dot, the second light control part having a second quantum dot, and the third light control part not having a quantum dot, wherein the light-emitting element has a first electrode, a hole transport region on the first electrode, a light-emitting layer on the hole transport region, an electron transport region on the light-emitting layer, and the second electrode on the electron transport region, the second quantum dot has a first shell around (e.g., surrounding) the core and including ZnTeSe, a second shell around (e.g., surrounding) the first shell and including ZnSe, and a third shell around (e.g., surrounding) the second shell, and including ZnS, the ratio of the number of moles of the Te in the first shell to the number of moles of the P in the core being about 0.02 to about 0.90.

In one or more embodiments, the light-emitting layer may be to emit first light with a center wavelength of about 440 nm to about 460 nm.

In one or more embodiments, the first quantum dot may be to absorb the first light, and to emit second light with a center wavelength of about 600 nm to about 640 nm, the second quantum dot may be to absorb light with a center wavelength of about 440 nm to about 460 nm, and to emit third light with a center wavelength of about 510 nm to about 540 nm, and the third light control part may be to transmit the first light emitted from the light-emitting layer.

In one or more embodiments, the display device may further include a color filter layer on the light control layer, the color filter layer having a first filter part to transmit the second light and overlapping the first light control part, a second filter part to transmit the third light and overlapping the second light control part, and a third filter part to transmit the first light and overlapping the third light control part.

In one or more embodiments, the first shell may be a layer most adjacent to the core (e.g., the layer closer to the core than the second shell and the third shell).

In one or more embodiments, a bandgap energy of the first shell may be less than a bandgap energy of the second shell, and a bandgap energy of the second shell may be less than a bandgap energy of the third shell.

In one or more embodiments of the present disclosure, a display device, having a first light-emitting region to emit first light, a second light-emitting region to emit second light, and a third light-emitting region to emit third light, includes a base layer, a first electrode on the base layer, a hole transport region on the first electrode, a light-emitting layer on the hole transport region and to emit the third light, an electron transport region on the light-emitting layer, a second electrode on the electron transport region, a first light control part in a region corresponding to the first light-emitting region on the second electrode and having a first quantum dot to absorb the third light and to emit the first light, a second light control part in a region corresponding to the second light-emitting region on the second electrode and having a second quantum dot to absorb the third light and to emit the second light, and a third light control part in a region corresponding to the third light-emitting region on the second electrode and to transmit the third light, wherein the second quantum dot has a core including InP, a first shell around (e.g., surrounding) the core and including ZnTeSe, a second shell around (e.g., surrounding) the first shell, and a third shell around (e.g., surrounding) the second shell, the ratio of the number of moles of the Te in the first shell to the number of moles of the P in the core being about 0.02 to about 0.90.

In one or more embodiments, the third light may have a center wavelength of about 440 nm to about 460 nm.

In one or more embodiments, the first light may have a center wavelength of about 600 nm to about 640 nm, and the second light may have a center wavelength of about 510 nm to about 540 nm.

In one or more embodiments, the first shell may be a layer most adjacent to the core (e.g., the layer closer to the core than the second shell and the third shell).

In one or more embodiments, a bandgap energy of the first shell may be less than a bandgap energy of the second shell, and a bandgap energy of the second shell may be less than a bandgap energy of the third shell.

In one or more embodiments, the second shell may include ZnSe, and the third shell may include ZnS.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of an electronic apparatus according to one or more embodiments of the present disclosure;

FIG. 2 is an exploded perspective view of an electronic apparatus according to one or more embodiments of the present disclosure;

FIG. 3 is a plan view illustrating one or more embodiments of a display device;

FIG. 4 is a cross-sectional view of a display device taken along line I-I′ of FIG. 3, according to one or more embodiments of the present disclosure;

FIG. 5 is a schematic drawing of a quantum dot according to one or more embodiments of the present disclosure; and

FIG. 6 is a cross-sectional view of a display device according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure. Embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

In contrast, when an element, such as a layer, a film, a region, or a substrate, is referred to as being “directly on,” “directly connected to” or “directly coupled to” another element, there are no intervening elements, such as a layer, a film, a region, or a substrate, present therebetween. For example, when an element is referred to as being “directly on,” two layers or members are disposed without an additional member, such as an adhesion member, being utilized therebetween.

Like reference numerals or symbols refer to like elements throughout, and duplicative descriptions thereof may not be provided. In the drawings, the thickness, the ratio, and the size of the element may be exaggerated for effective description of the technical contents.

As used herein, the term “and/or” includes any and all combinations of one or more of the associated listed items.

It will be understood that, although the terms “first,” “second,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the present disclosure. Similarly, a second element, component, region, layer or section may be termed a first element, component, region, layer or section. As used herein, the singular forms, “a,” “an,” and “the” are intended to include the plural forms as well, unless the context clearly indicates otherwise. Spatially relative terms, such as “below,” “on a lower side,” “above,” “on an upper side,” and/or the like may be used herein for ease of explanation to describe the relationships of the elements illustrated in the drawings. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c”, etc., indicates only a, only b, only c, both a and b, both a and c, both b and c, all of a, b, and c, or variations thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense unless expressly so defined herein.

It will be further understood that the terms “comprises,” “includes” and/or “have,” when used in this specification, specify the presence of the stated features, integers, steps, operations, elements, components, and/or groups thereof, but do not preclude the presence or addition of one or more other features, integers, steps, operations, elements, components, and/or groups thereof.

Hereinafter, a quantum dot according to one or more embodiments of the present disclosure, and a display device including the quantum dot will be described with reference to the accompanying drawings.

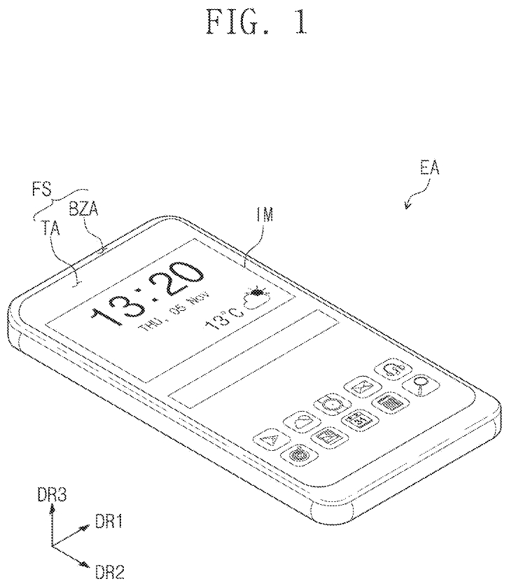

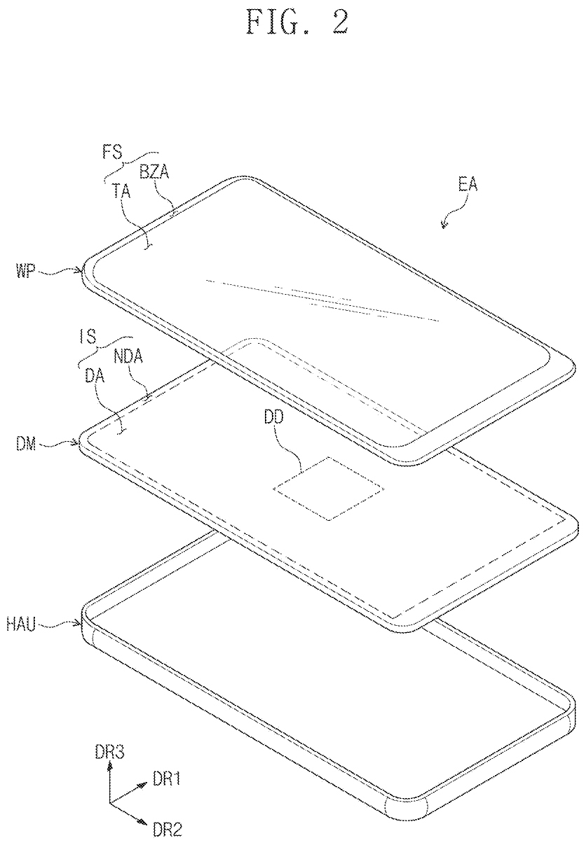

FIG. 1 is a perspective view of an electronic apparatus according to one or more embodiments of the present disclosure. FIG. 2 is an exploded perspective view of the electronic apparatus according to one or more embodiments of the present disclosure.

Referring to FIGS. 1 and 2, an electronic apparatus EA according to one or more embodiments may be a large electronic apparatus such as a television, a monitor, or a billboard. In one or more embodiments, the electronic apparatus EA may be a small- or medium-sized electronic apparatus such as a personal computer, a laptop computer, a personal digital assistant, a car navigation unit, a game console, a smartphone, a tablet computer, and/or a camera. Moreover, those listed above are merely presented as examples of the electronic apparatus ED, and other apparatuses may also be employed without departing from the scope of the present disclosure. In this embodiment, a smartphone is illustrated as an example of the electronic apparatus EA.

The electronic apparatus EA may include a display device DD and a housing HAU. The display device DD may display an image IM through a display surface IS. FIG. 1 illustrates that the display surface IS is parallel to the surface defined by a first direction DR1 and a second direction DR2 crossing the first direction DR1. However, this is only an example, and in another embodiment, the display surface IS of the display device DD may have a curved shape.

A third direction DR3 indicates the direction normal to the display surface IS, that is, a direction in which the image IM is displayed in the thickness direction of the display device DD. A front surface (or top surface) and a rear surface (or bottom surface) of each member may be distinguished based on the third direction DR3. In one or more embodiments, the directions indicated by the first through third directions DR1, DR2, and DR3 are relative concepts, and may thus be changed to other directions.

In the electronic apparatus EA, the display surface FS on which the image IM is displayed may correspond to a front surface of the display device DD, and may correspond to a front surface FS of a window WP. Hereinafter, a display surface and a front surface of the electronic apparatus EA, and a front surface of the window WP are denoted as the same reference numeral or symbol. The image IM may include a still image as well as a dynamic image. In one or more embodiments, the electronic apparatus EA may include a foldable display device having a folding region and a non-folding region, and/or may include a bendable display device having at least one bending part.

The housing HAU may accommodate the display device DD. The housing HAU may be disposed to cover the display device DD such that an upper surface, which is the display surface IS of the display device DD, is exposed. The housing HAU may cover the side surfaces and the bottom surface of the display device DD, and expose the entire upper surface of the display device DD. However, the present disclosure is not limited thereto, and the housing HAU may cover not only the side surfaces and the bottom surface, but also a portion of the upper surface of the display device DD.

In the electronic apparatus EA according to one or more embodiments, the window WP may include an optically transparent insulating material. The window WP may include a transmission region TA and a bezel region BZA. The front surface FS of the window WP including the transmission region TA and the bezel region BZA corresponds to the front surface FS of the electronic apparatus EA. A user may view an image provided through the transmission region TA corresponding to the front surface FS of the electronic apparatus EA.

FIGS. 1 and 2 illustrate that the transmission region TA has a quadrilateral shape with rounded corners. However, this is illustrated as an example, and the transmission region TA may have one or more suitable shapes, and the present disclosure is not limited to any one embodiment.

The transmission region TA may be optically transparent. The bezel region BZA may be a region having a light transmittance relatively lower than the transmission region TA. The bezel region BZA may have a set or predetermined color. The bezel region BZA may be adjacent to the transmission region TA, and may surround the transmission region TA. The bezel region BZA may define the shape of the transmission region TA. However, the present disclosure is not limited to what is illustrated in the embodiment, and the bezel region BZA may be disposed adjacent only to one side of the transmission region TA, and a portion of the bezel region BZA may not be provided.

The display device DD may be disposed under the window WP. In this specification, the term “under” may refer to the direction opposite to the direction in which the display device DD provides an image.

In one or more embodiments, the display device DD may be configured to substantially generate the image IM. The image IM generated by the display device DD is displayed on the display surface IS, and is viewed by a user from the outside through the transmission region TA. The display device DD includes a display region DA and a non-display region NDA. The display region DA may be a region activated in response to electrical signals. The non-display region NDA may be a region covered by the bezel region BZA. The non-display region NDA is adjacent to the display region DA. The non-display region NDA may surround the display region DA.

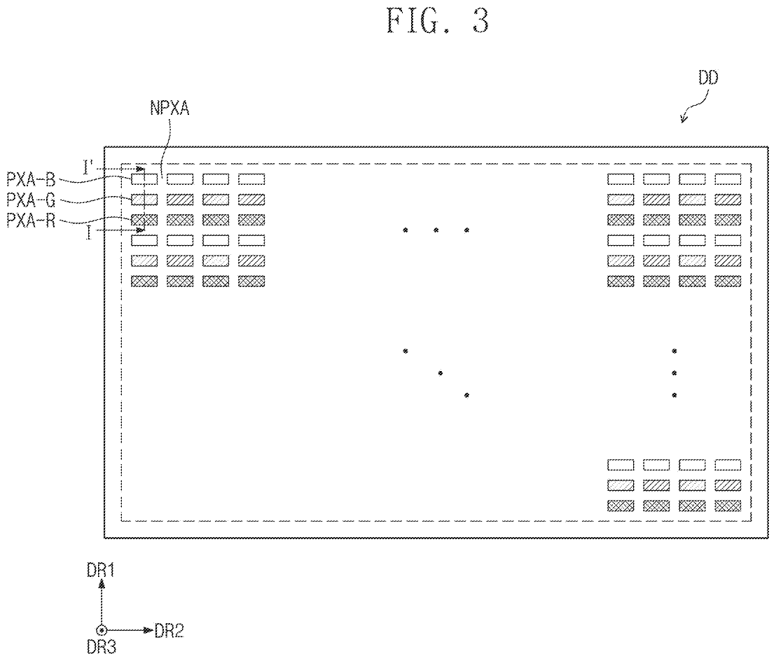

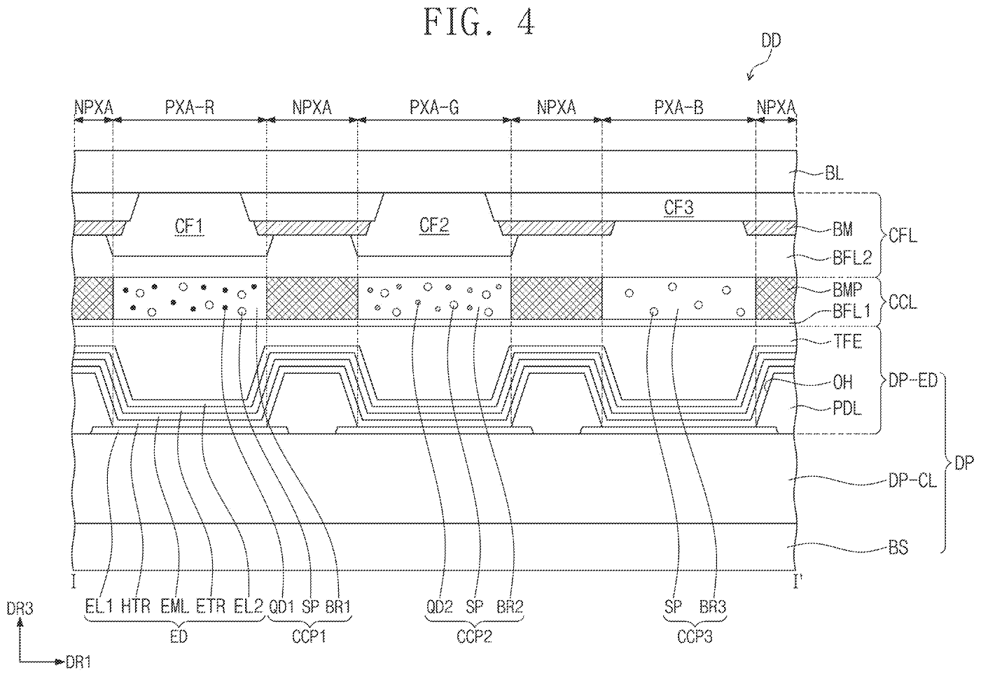

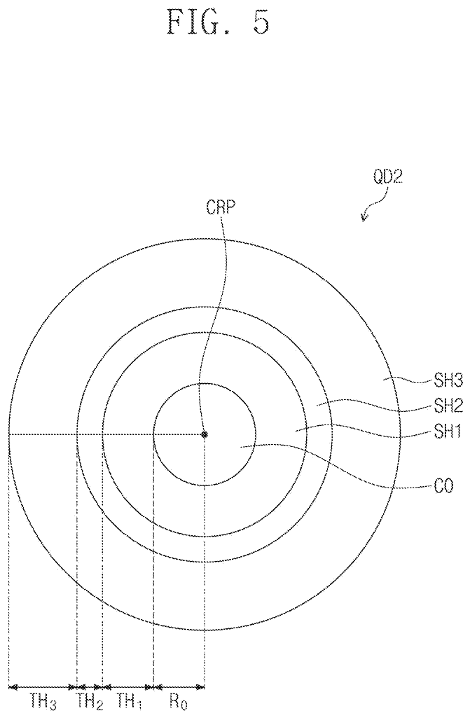

FIG. 3 is a plan view illustrating one or more embodiments of a display device. FIG. 4 is a cross-sectional view of the display device according to one or more embodiments of the present disclosure. FIG. 4 is a cross-sectional view taken along line I-I′ of FIG. 3. FIG. 5 schematically illustrates a quantum dot according to one or more embodiments of the present disclosure. FIG. 5 is a view schematically illustrating a quantum dot included in a light control layer illustrated in FIG. 4.

Referring to FIGS. 3 and 4, the display device DD according to one or more embodiments may include a display panel DP, a light control layer CCL disposed on the display panel DP, and a color filter layer CFL disposed on the light control layer CCL. The display panel DP includes a light-emitting element ED.

A base substrate BL may be disposed on the color filter layer CFL. The base substrate BL may be a member that provides a base surface on which the color filter layer CFL is disposed. The base substrate BL may be a glass substrate, a metal substrate, a plastic substrate, and/or the like. However, the present disclosure is not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be disposed between a display element layer DP-ED and the base substrate BL. The filling layer may be an organic material layer. The filling layer may include at least one of an acryl-based resin, a silicone-based resin, or an epoxy-based resin.

The display panel DP may include a base layer BS, and a circuit layer DP-CL and a display element layer DP-ED provided on the base layer BS. The display element layer DP-ED may include pixel defining films PDL, a light-emitting element ED disposed between the pixel defining films PDL, and an encapsulation layer TFE disposed on the light-emitting element ED.

The base layer BS may be a member that provides a base surface on which the display element layer DP-ED is disposed. The base layer BS may be a glass substrate, a metal substrate, a plastic substrate, and/or the like. However, the present disclosure is not limited thereto, and the base layer BS may be an inorganic layer, an organic layer, or a composite material layer.

In one or more embodiments, the circuit layer DP-CL may be disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light-emitting element ED of the display element layer DP-ED.

The light-emitting element ED may include a first electrode EL1, a hole transport region HTL, a light-emitting layer EML, an electron transport region ETR, and a second electrode EL2.

FIG. 4 illustrates one or more embodiments in which the hole transport region HTR, the light-emitting layer EML, the electron transport region ETR, and the second electrode EL2 are provided as common layers throughout the display element layer DP-ED. However, the present disclosure is not limited thereto, and in one or more embodiments, the hole transport region HTR, the light-emitting layer EML, and the electron transport region ETR may be provided by being patterned inside openings OH which are defined in the pixel defining films PDL. For example, in one or more embodiments, the hole transport region HTR, the light-emitting layer EML, the electron transport layer ETR, and/or the like of the light-emitting element ED may be provided by being patterned through inkjet printing.

In the light-emitting element ED according to one or more embodiments, the first electrode EL1 is conductive. The first electrode EL1 may be formed of a metal alloy or a conductive compound. The first electrode EL1 may be an anode. The first electrode EL1 may be a pixel electrode.

In the light-emitting element ED according to one or more embodiments, the first electrode EL1 may be a reflective electrode. However, the present disclosure is not limited thereto. For example, the first electrode EL1 may be a transmissive electrode or a transflective electrode. When the first electrode EL1 is a transflective electrode or a reflective electrode, the first electrode EL1 may include (e.g., contain) Ag, Mg, Cu, Al, Pt, Pd, Au, Ni, Nd, Ir, Cr, Li, Ca, LiF/Ca (e.g., a layer of LiF and a layer of Ca), LiF/Al (e.g., a layer of LiF and a layer of Al), Mo, Ti, or a compound or a mixture (e.g., a mixture of Ag and Mg) thereof. In one or more embodiments, the first electrode EL1 may have a multi-layer structure including a reflective or transflective film made of any of the materials above, and a transparent conductive film made of indium tin oxide (ITO), indium zinc oxide (IZO), zinc oxide (ZnO), indium tin zinc oxide (ITZO), and/or the like. For example, the first electrode EL1 may be a multi-layer metal film, and may have a structure in which metal films of ITO/Ag/ITO are stacked.

The hole transport region HTR is provided on the first electrode EL1. The hole transport region HTR may include a hole injection layer and a hole transport layer. In one or more embodiments, the hole transport region HTR may further include at least one of a hole buffer layer or an electron blocking layer besides the hole injection layer and the hole transport layer. The hole buffer layer may compensate for the resonance distance according to the wavelength of light emitted from the light-emitting layer EML, thereby improving the light emission efficiency. Materials, which may be included in the hole transport region HTR, may be utilized as materials to be included in the hole buffer layer. The electron blocking layer is a layer that prevents the injection of electrons from the electron transport region ETR to the hole transport region HTR.

The hole transport region HTR may be a single layer made of a single material, a single layer made of a plurality of materials different from each other, or may have a multi-layer structure including a plurality of layers made of a plurality of materials different from each other. For example, the hole transport region HTR may have a structure including single layers made of a plurality of materials different from each other, or may have a stacked structure in which a hole injection layer/a hole transport layer, a hole injection layer/a hole transport layer/a hole buffer layer, a hole injection layer/a hole buffer layer, a hole transport layer/a hole buffer layer, a hole buffer layer/a hole transport layer, a hole injection layer/a hole transport layer/an electron blocking layer, a hole buffer layer/a hole injection layer/a hole transport layer, and/or the like are stacked in sequence from the first electrode EL1, but the present disclosure is not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, a laser induced thermal imaging (LITI) method, and/or the like.

The electron transport region ETR may be a single layer made of a single material, a single layer made of a plurality of materials different from each other, or may have a multi-layer structure including a plurality of layers made of a plurality of materials different from each other.

For example, the electron transport region ETR may have a single-layer structure including an electron injection layer or an electron transport layer, and may also have a structure including a single layer made of an electron injection material and an electron transport material. In one or more embodiments, the electron transport region ETR may have a structure including a single layer made of a plurality of materials different from each other, or may have a stacked structure in which an electron transport layer/an electron injection layer, or a hole blocking layer/an electron transport layer/an electron injection layer are stacked in sequence from the light-emitting layer EML, but the structure of the electron transport region ETR is not limited thereto. The thickness of the electron transport region ETR may be, for example, about 200 Å to about 1500 Å.

The light-emitting layer EML is provided on the hole transport region HTR. The light-emitting layer EML may have a thickness of, for example, about 100 Å to about 1000 Å, or about 100 Å to about 300 Å. The light-emitting layer EML may be a single layer made of a single material, a single layer made of a plurality of materials different from each other, or may have a multi-layer structure including a plurality of layers made of a plurality of materials different from each other.

In the light-emitting element ED according to one or more embodiments, the light-emitting layer EML may include an anthracene derivative, a pyrene derivative, a fluoranthene derivative, a chrysene derivative, a dihydrobenzanthracene derivative, or a triphenylene derivative. In one or more embodiments, the light-emitting layer EML may include an anthracene derivative or a pyrene derivative. In one or more embodiments, the light-emitting layer EML may be to emit light with a center wavelength of about 440 nm to about 460 nm.

The electron transport region ETR may be formed utilizing one or more suitable methods such as a vacuum deposition method, a spin coating method, a casting method, a Langmuir-Blodgett (LB) method, an inkjet printing method, a laser printing method, a laser induced thermal imaging (LITI) method, and/or the like.

When the electron transport region ETR includes an electron transport layer, the electron transport region ETR may include (e.g., contain) an anthracene-based compound. However, the present disclosure is not limited thereto, and the electron transport region may include (e.g., contain), for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (BAlq), berylliumbis(benzoquinolin-10-olate (Bebq₂), 9,10-di(naphthalene-2-yl)anthracene (ADN), and/or a mixture thereof. The thickness of the electron transport layer may be about 100 Å to about 1000 Å, for example, about 150 Å to about 500 Å. When the electron transport layer has a thickness satisfying the above-mentioned range, a satisfactory level of electron transport characteristics may be obtained without a substantial increase in the driving voltage.

When the electron transport region ETR includes an electron injection layer, the electron transport region ETR may include a metal halide, a lanthanide metal, a co-deposition material of a metal halide and a lanthanide metal, and/or the like. In one or more embodiments, the metal halide may be an alkali metal halide. For example, the electron transport region ETR may include (e.g., contain) LiF, lithium quinolate (Liq), Li₂O, BaO, NaCl, CsF, Yb, RbCl, RbI, KI, or KI:Yb, but the present disclosure is not limited thereto. In one or more embodiments, the electron injection layer may be made of a mixture of an electron transport material and insulative organo-metal salt. For example, the organo-metal salt may include (e.g., contain) metal acetate, metal benzoate, metal acetoacetate, metal acetylacetonate, or metal stearate. The electron injection layer may have a thickness of about 1 Å to about 100 Å, or about 3 Å to about 90 Å. When the electron injection layer has a thickness satisfying the above-mentioned range, a satisfactory level of electron injection characteristics may be obtained without a substantial increase in the driving voltage.

The electron transport region ETR, as previously mentioned, may include a hole blocking layer. The hole blocking layer may include (e.g., contain) at least one of, for example, 2,9-dimethyl-4,7-diphenyl-1,10-phenanthroline (BCP), or 4,7-diphenyl-1,10-phenanthroline (Bphen), but the present disclosure is not limited thereto.

The second electrode EL2 is provided on the electron transport region ETR. The second electrode EL2 may be a common electrode or a negative electrode. The second electrode EL2 may be a transmissive electrode, a transflective electrode, or a reflective electrode. When the second electrode EL2 is a transmissive electrode, the second electrode EL2 may be made of a transparent metal oxide, for example, indium tin oxide (ITO), indium zinc oxide (IZO), zinc oxide (ZnO), indium tin zinc oxide (ITZO), and/or the like.

When the second electrode EL2 is a transflective electrode or a reflective electrode, the second electrode EL2 may include (e.g., contain) Ag, Mg, Cu, Al, Pt, Pd, Au, Ni, Nd, Ir, Cr, Li, Ca, LiF/Ca (e.g., a layer of LiF and a layer of Ca), LiF/Al (e.g., a layer of LiF and a layer of Al), Mo, Ti, or a compound or a mixture (e.g., a mixture of Ag and Mg). In one or more embodiments, the second electrode EL2 may have a muti-layer structure including a reflective or a transflective film made of the above materials and a transparent conductive film formed of indium tin oxide (ITO), indium zinc oxide (IZO), zinc oxide (ZnO), indium tin zinc oxide (ITZO), and/or the like.

In one or more embodiments, the second electrode EL2 may be connected to an auxiliary electrode. When the second electrode EL2 is connected to the auxiliary electrode, the resistance of the second electrode EL2 may be reduced.

An encapsulation layer TFE may cover the light-emitting element ED. The encapsulation layer TFE may seal the display element layer DP-ED. The encapsulation layer TFE may be a thin-film encapsulation layer. The encapsulation layer TFE may have a single layer, or may have stacked multi-layers. The encapsulation layer TFE includes at least one insulation layer. The encapsulation layer TFE according to one or more embodiments may include at least one inorganic film (hereinafter, an inorganic encapsulation film). In one or more embodiments, the encapsulation layer TFE according to one or more embodiments may include at least one organic film (hereinafter, an organic encapsulation film), and at least one inorganic encapsulation film.

The inorganic encapsulation film protects the display element layer DP-ED from moisture and/or oxygen, and the organic encapsulation film protects the display element layer DP-ED from foreign substances such as dust particles. The inorganic encapsulation film may include silicon nitride, silicon oxynitride, silicon oxide, titanium oxide, aluminum oxide, and/or the like, but the present disclosure is not limited thereto. The organic encapsulation film may include an acryl-based compound, an epoxy-based compound, and/or the like. The organic encapsulation film may include a photopolymerizable organic material, but the present disclosure is not limited particularly thereto.

The encapsulation layer TFE may be disposed on the second electrode EL2. The encapsulation layer TFE may be disposed filling the openings OH.

The light control layer CCL may be disposed on the display panel DP. The light control layer CCL may include a photoconverter. The photoconverter may be a quantum dot or a phosphor. The photoconverter may convert the wavelength of received light, and emit the wavelength-converted light. For example, the light control layer CCL may be a layer including quantum dots, or a layer including phosphors.

The light control layer CCL may include a plurality of light control parts CCP1, CCP2, and CCP3. The light control parts CCP1, CCP2, and CCP3 may be spaced apart from each other.

Referring to FIG. 4, partitioning patterns BMP may be disposed between the light control parts CCP1, CCP2, and CCP3 that are spaced apart from each other, but the present disclosure is not limited thereto. FIG. 4 illustrates that the partitioning patterns BMP do not overlap the light control parts CCP1, CCP2, and CCP3, but the edges of the light control parts CCP1, CCP2, and CCP3 may overlap at least a portion of the partitioning patterns BMP.

The light control layer CCL may include a first light control part CCP1 which has a first quantum dot QD1 for converting third light provided by the light-emitting element DP-ED to first light, a second light control part CCP2 which has a second quantum dot QD2 for converting the third light to second light, and a third light control part CCP3 which transmits the first light. The third light may have a center wavelength of about 440 nm to about 460 nm, the first light may have a center wavelength of about 600 nm to about 640 nm, and the second light may have a center wavelength of about 510 nm to about 540 nm.

In one or more embodiments, the first light control part CCP1 may provide red light which is the first light, and the second light control part CCP2 may provide green light which is the second light. The third light control part CCP3 may be to transmit blue light which is the third light provided by the light-emitting element ED, and may provide the blue light. For example, the first quantum dot QD1 may be a red quantum dot, and the second quantum dot QD2 may be a green quantum dot. The same description as what has been previously described may be applied to the quantum dots QD1 and QD2.

Moreover, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) a quantum dot, and may include the scatterer SP.

The scatterer SP may be an inorganic particle. For example, the scatterer SP may include (e.g., contain) at least one of TiO₂, ZnO, Al₂O₃, SiO₂, or hollow silica. The scatterer SP may include (e.g., contain) at least one of TiO₂, ZnO, Al₂O₃, SiO₂, or hollow silica, or may be a mixture of two or more substances selected from among TiO₂, ZnO, Al₂O₃, SiO₂, and hollow silica.

The first light control part CCP1, the second light control part CCP2, and the third light control part CCP3 may respectively include base resins BR1, BR2, and BR3 in which the quantum dots QD1 and QD2, and the scatterer SP are dispersed. In one or more embodiments, the first light control part CCP1 may include the first quantum dot QD1 and the scatterer SP that are dispersed in a first base resin BR1, the second light control part CCP2 may include the second quantum dot QD2 and the scatterer SP that are dispersed in a second base resin BR2, and the third light control part CCP3 may include the scatterer SP dispersed in a third base resin BR3. The base resins BR1, BR2, and BR3, which are media in which the quantum dots QD1 and QD2 and the scatterer SP are dispersed, may be formed of one or more suitable resin compositions generally referred to as binders. For example, the base resins BR1, BR2, and BR3 may each be an acryl-based resin, a urethane-based resin, a silicone-based resin, an epoxy-based resin, and/or the like. The base resins BR1, BR2, and BR3 may be transparent resins. In one or more embodiments, the first base resin BR1, the second base resin BR2, and the third base resin BR3 may be equal to (e.g., the same as), or different from each other.

The light control layer CCL may include a barrier layer BFL1. The barrier layer BFL1 may serve to prevent or reduce the penetration of moisture and/or oxygen (hereinafter, referred to as moisture/oxygen). The barrier layer BFL1 may be disposed on the light control parts CCP1, CCP2, and CCP3, and thus prevent or reduce the light control parts CCP1, CCP2, and CCP3 from being exposed to moisture/oxygen. In one or more embodiments, the barrier layer BFL1 may cover the light control parts CCP1, CCP2, and CCP3. In one or more embodiments, a barrier layer BFL2 may also be provided between the light control parts CCP1, CCP2, and CCP3 and the color filter layer CFL.

The barrier layer BFL1 or BFL2 may include at least one inorganic layer. For example, the barrier layer BFL1 or BFL2 may be formed including an inorganic material. For example, the barrier layer BFL1 or BFL2 may be formed including silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, or a metal thin film with a secured light transmittance, and/or the like. In one or more embodiments, the barrier layer BFL1 or BFL2 may further include an organic film. The barrier layer BFL1 or BFL2 may have a single layer or a multi-layered structure.

In the display device DD according to one or more embodiments, the color filter layer CFL may be disposed on the light control layer CCL. For example, the color filter layer CFL may be directly disposed on the light control layer CCL. In such cases, the barrier layer BFL2 may not be provided.

The color filter layer CFL may include a light blocking part BM and filters CF1, CF2, and CF3. The color filter layer CFL may include a first filter CF1 which transmits the first light, a second filter CF2 which transmits the second light, and the third filter CF3 which transmits the third light. For example, the first filter CF1 may be a red filter, the second filter CF2 may be a green filter, and the third filter CF3 may be a blue filter. Each of the filters CF1, CF2, and CF3 may include a polymer photosensitive resin, and a piment or a dye. The first filter CF1 may include a red pigment or dye, the second filter CF2 may include a green pigment or dye, and the third filter CF3 may include a blue pigment or dye. However, the present disclosure is not limited thereto, and the third filter CF3 may not include (e.g., may exclude) a pigment or a dye. The third filter CF3 may include a polymer photosensitive resin, and may not include (e.g., may exclude) a pigment or a dye. The third filter CF3 may be transparent. The third filter CF3 may be formed of a transparent photosensitive resin.

In one or more embodiments, the first filter CF1 and the second filter CF2 may be yellow filters. The first filter CF1 and the second filter CF2 may not be divided, and may be provided in one piece.

The light blocking part BM may be a black matrix. The light blocking part BM may be formed of an organic or inorganic light blocking material containing a black pigment or a black dye. The light blocking part BM may prevent or reduce light leakage, and may demarcate the adjacent filters CF1, CF2, and CF3. In one or more embodiments, the light blocking part BM may be formed of a blue filter.

The first, second, and third filters CF1, CF2, and CF3 may be disposed corresponding to a red light-emitting region PXA-R, a green light-emitting region PXA-G, and a blue light-emitting region PXA-B, respectively.

Referring to FIGS. 3 and 4, the display device DD may include a non-light-emitting region NPXA and the light-emitting regions PXA-R, PXA-G, and PXA-B. Each of the light-emitting regions PXA-R, PXA-G, and PXA-B may be a region emitting light generated from each light-emitting element ED. The light-emitting regions PXA-R, PXA-G, and PXA-B may be spaced apart from each other on a plane (e.g., in a plan view).

The light-emitting regions PXA-R, PXA-G, and PXA-B may be regions separated by the pixel defining films PDL. The non-light-emitting regions NPXA may be regions disposed between the light-emitting regions PXA-R, PXA-G, and PXA-B adjacent thereto, and corresponding to the pixel defining films PDL. In one or more embodiments, in this specification, each of the light-emitting regions PXA-R, PXA-G, and PXA-B may correspond to a pixel.

The light-emitting regions PXA-R, PXA-G, and PXA-B may be classified into a plurality of groups according to the color of light emitted from the light control layer CCL. In the display device DD according to one or more embodiments illustrated in FIGS. 3 and 4, three light-emitting regions PXA-R, PXA-G, and PXA-B emitting red light, green light, and blue light, respectively, are illustrated as an example. For example, the display device DD according to one or more embodiments may include a red light-emitting region PXA-R, a green light-emitting region PXA-G, and a blue light-emitting region PXA-B which are distinct from each other.

In the display device DD according to one or more embodiments, the light-emitting regions PXA-R, PXA-G, and PXA-B may be arranged in a stripe shape. Referring to FIG. 3, a plurality of the red light-emitting regions PXA-R, a plurality of the green light-emitting regions PXA-G, and a plurality of the blue light-emitting regions PXA-B may each be aligned along the second direction DR2. In one or more embodiments, the red light-emitting region PXA-R, the green light-emitting region PXA-G, and the blue light-emitting region PXA-B may be arranged alternately in this order along the first direction axis DR1.

FIGS. 3 and 4 illustrate that all the areas of the light-emitting regions PXA-R, PXA-G, and PXA-B are similar, but the present disclosure is not limited thereto, and the areas of the light-emitting regions PXA-R, PXA-G, and PXA-B may be different from each other according to the wavelength range of light emitted. In one or more embodiments, the areas of the light-emitting regions PXA-R, PXA-G, and PXA-B may refer to the areas when viewed on the plane defined by the first direction axis DR1 and the second direction axis DR2.

In one or more embodiments, the arrangement of the light-emitting regions PXA-R, PXA-G, and PXA-B is not limited to what is illustrated in FIG. 3, and the order in which the red light-emitting region PXA-R, the green light-emitting region PXA-G, and the blue light-emitting region PXA-B are arranged may be provided in one or more suitable combinations according to the display quality characteristics required by the display device DD. For example, the arrangement of the light-emitting regions PXA-R, PXA-G, and PXA-B may be the PENTILE® arrangement, or the Diamond Pixel® arrangement. PENTILE® and DIAMOND PIXEL® are registered trademarks of Samsung Display Co., Ltd., a Korean company.

In one or more embodiments, the areas of the light-emitting regions PXA-R, PXA-G, and PXA-B may be different from each other. For example, in one or more embodiments, the area of the green light-emitting region PXA-G may be smaller than the area of the blue light-emitting region PXA-B, but the present disclosure is not limited thereto.

Referring to FIG. 5, the second quantum dot QD2 according to one or more embodiments may include a core CO, a first shell SH1, a second shell SH2, and a third shell SH3. The first shell SH1 may be around (e.g., may surround) the core CO. The second shell SH2 may be around (e.g., may surround) the first shell SH1. The third shell SH3 may be around (e.g., may surround) the second shell SH2. FIG. 5 illustrates that three shell layers surround the core CO, but the present disclosure is not limited thereto. For example, the second quantum dot QD2 may include a core and four shells around (e.g., surrounding) the core. For example, the second quantum dot QD2 may further include a fourth shell around (e.g., surrounding) the third shell SH3. In one or more embodiments, a quantum dot QD may further include a ligand that is bonded to the surface thereof.

In one or more embodiments, the core CO may include InP. The core CO may include a center part CRP. The core CO may have a spherical shape. When the core CO has a spherical shape, the radius of the core CO may be defined as a distance R₀ from the center part CRP to the surface of the core CO.

In the second quantum dot QD2 according to one or more embodiments, the core CO may be to absorb external light. The core CO may be to absorb external light, and then may be to emit light having a wavelength different from that of the light absorbed. For example, the core CO may be to absorb light having a center wavelength of about 440 nm to about 460 nm, and then may be to emit light having a center wavelength of about 510 nm to about 540 nm. In one or more embodiments, the core CO may further absorb light having a center wavelength of about 440 nm or less, or greater than about 460 nm. The core CO may be to absorb light having a center wavelength of about 440 nm or less, or greater than about 460 nm, and then may be to emit light having a center wavelength of about 510 nm to about 540 nm.

The first shell SH1 may be directly disposed on the core CO. The first shell SH1 may be a layer most adjacent to the core CO (e.g., closer to the core CO than the second and third shells SH2, SH3). The first shell SH1 may include ZnTeSe. The first shell SH1 may be to absorb light having a center wavelength of about 440 nm to about 460 nm. A bandgap energy of the first shell SH1 may be less than a bandgap energy of the second shell SH2. A bandgap energy of the third shell SH3 may be less than the bandgap energy of the first shell SH1. Accordingly, the first shell SH1 may be to absorb light having a center wavelength of about 440 nm to about 460 nm, and each of the second shell SH2 and the third shell SH3 may not absorb light having a center wavelength of about 440 nm to about 460 nm. For example, the bandgap energy of each of the second shell SH2 and the third shell SH3 may be greater than the energy of light having a center wavelength of about 440 nm to about 460 nm. In one or more embodiments, the bandgap energy of the first shell SH1 may be less than the energy of light having a center wavelength of about 440 nm to about 460 nm.

The core CO including InP, according to one or more embodiments, may have a discontinuous energy level due to the quantum confinement effect, and may have a low light absorption rate for light having a center wavelength of about 440 nm to about 460 nm. The second quantum dot QD2 according to one or more embodiments may have excellent or suitable light absorption rate for light having a center wavelength of about 440 nm to about 460 nm by including the first shell SH1 which has excellent or suitable light absorption rate for light having a center wavelength of about 440 nm to about 460 nm. Accordingly, the second quantum dot QD2 including the first shell SH1 may have excellent or suitable external quantum efficiency.

In one or more embodiments, the ratio of the number of moles of Te included (e.g., contained) in the first shell SH1 to the number of moles of P included (e.g., contained) in the core CO may be about 0.02 to about 0.90. When the ratio of the number of moles of Te included (e.g., contained) in the first shell SH1 to the number of moles of P included (e.g., contained) in the core CO is less than about 0.02, the effect of absorbing, by the first shell SH1, blue light may be insignificant, and thus the increase in external quantum efficiency of the second quantum dot QD2 may also be insignificant. When the ratio of the number of moles of Te included (e.g., contained) in the first shell SH1 to the number of moles of P included (e.g., contained) in the core CO is greater than about 0.90, this affects the bandgap energy of the second quantum dot QD2, so that the second quantum dot QD2 may be to emit light having a center wavelength less than about 510 nm, or greater than about 540 nm.

Each of the second shell SH2 and the third shell SH3 may include a Group II-VI compound. The Group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. For example, the second shell SH2 may include ZnSe. The third shell SH3 may include ZnS.

In one or more embodiments, when the second shell SH2 includes ZnSe, and the third shell SH3 includes ZnS, the number of moles of Se included (e.g., contained) in the second shell SH2 may be greater than the number of moles of Te included (e.g., contained) in the first shell SH1. In one or more embodiments, the number of moles of S included (e.g., contained) in the third shell SH3 may be greater than the number of moles of Te included (e.g., contained) in the first shell SH1.

FIG. 4 illustrates that a thickness TH₁ of the first shell SH1 is greater than a thickness TH₂ of the second shell SH2, and the thickness TH₁ of the first shell SH1 may be less than a thickness TH₃ of the third shell SH3, but this is merely an example, and the present disclosure is not limited thereto. For example, the thickness TH₁ of the first shell SH1 may be greater than the thickness TH₃ of the third shell SH3, and may be less than the thickness TH₂ of the second shell SH2, or the respective thicknesses TH₁, TH₂, and TH₃ of the first, second, and third shells SH1, SH2, and SH3 may be substantially uniform.

In one or more embodiments, the second quantum dot QD2 according to one or more embodiments may have a diameter of about 5 nm to about 7 nm. The diameter of the second quantum dot QD2 is defined as the sum of the radius R₀ of the core CO and the thicknesses TH₁ through TH₃ of the first through third shells SH1 through SH3.

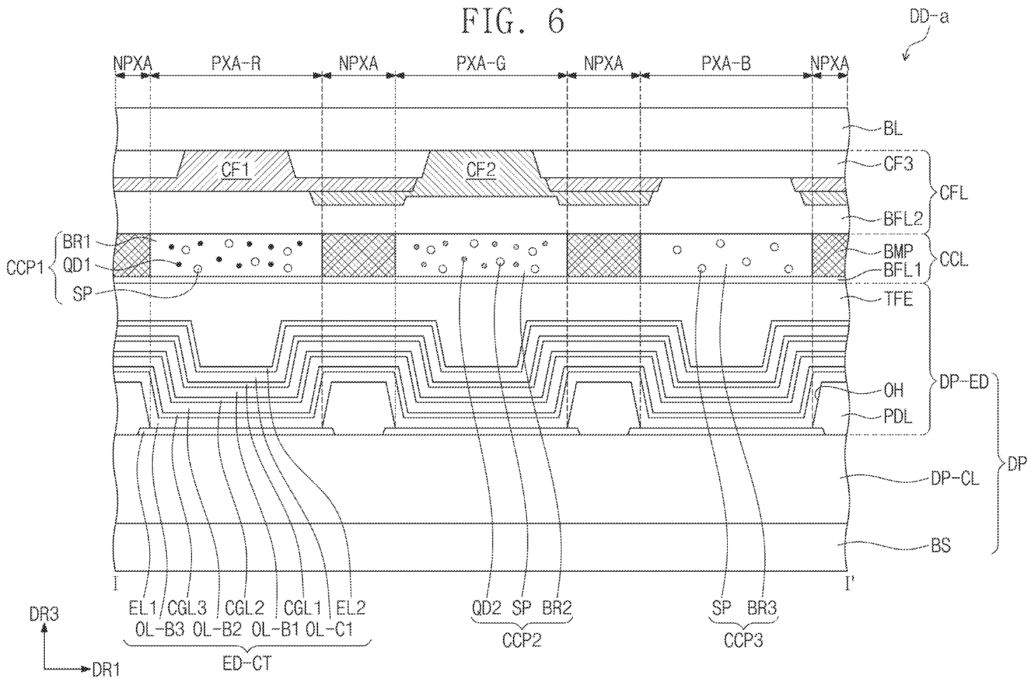

FIG. 6 is a cross-sectional view of a display device according to one or more embodiments. The content overlapping with what has been described with reference to FIGS. 1 through 5 are not described again, and the differences are mainly described.

FIG. 6 illustrates that unlike the display device illustrated in FIG. 4, a display device DD-a includes four light-emitting structures OL-B1, OL-B2, OL-B3, and OL-C1. A light-emitting element ED-CT may include a first electrode EL1 and a second electrode EL2 which face each other, and a first through fourth light-emitting structures OL-B1, OL-B2, OL-B3, and OL-C1 stacked in sequence in a thickness direction between the first electrode EL1 and the second electrode EL2. Charge generation layers CGL1, CGL2, and CGL3 may be disposed between the first through fourth light-emitting structures OL-B1, OL-B2, OL-B3, and OL-C1. The first, second, and third light-emitting structures OL-B1, OL-B2, and OL-B3 among the four light-emitting structures may be to emit blue light, and the fourth light-emitting structure OL-C1 may be to emit green light. However, the present disclosure is not limited thereto, and each of the first through fourth light-emitting structures OL-B1, OL-B2, OL-B3, and OL-C1 may be to emit light having different wavelength ranges.

The charge generation layers CGL1, CGL2, and CGL3 disposed between the adjacent light-emitting structures OL-B1, OL-B2, OL-B3, and OL-C1 may include a p-type or kind charge generation layer and/or an n-type or kind charge generation layer.

A quantum dot according to one or more embodiments includes a core, and first through third shells around (e.g., surrounding) the core. The core includes InP, the first shell includes ZnTeSe, and the ratio of the number of moles of Te included (e.g., contained) in the first shell to the number of moles of P included (e.g., contained) in the core is about 0.02 to about 0.90. The first shell absorbs light having a center wavelength of about 440 nm to about 460 nm. Accordingly, the quantum dot including the first shell may have excellent or suitable external quantum efficiency. Moreover, a display device according to one or more embodiments may include a light control layer having a quantum dot which has excellent or suitable external quantum efficiency, and may thus have excellent or suitable luminous efficiency.

A quantum dot according to one or more embodiments may have external quantum efficiency.

One or more embodiments of the present disclosure may also provide a display device having excellent or suitable luminous efficiency by including a light control layer which has a quantum dot with excellent or suitable external quantum efficiency.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, when particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

Although the embodiments of the present disclosure have been described, it is understood that the present disclosure should not be limited to these embodiments but one or more suitable changes and modifications can be made by one ordinary skilled in the art within the spirit and scope of the present disclosure as defined by the following claims and equivalents thereof.

What is claimed is:

1. A quantum dot comprising:
a core comprising InP;
a first shell around the core, and comprising ZnTeSe;
a second shell around the first shell, and comprising ZnSe; and
a third shell around the second shell, and comprising ZnS,
wherein a ratio of a number of moles of the Te in the first shell to a number of moles of the P in the core is about 0.02 to about 0.90.

2. The quantum dot of claim 1, wherein the first shell absorbs light with a center wavelength of about 440 nm to about 460 nm.

3. The quantum dot of claim 1, wherein the first shell is closer to the core than the second shell and the third shell.

4. The quantum dot of claim 1, wherein a bandgap energy of the first shell is less than a bandgap energy of the second shell and less than a bandgap energy of the third shell.

5. The quantum dot of claim 1, wherein the quantum dot is to emit light with a center wavelength of about 510 nm to about 540 nm.

6. The quantum dot of claim 1, wherein the quantum dot has a diameter of about 5 nm to about 7 nm.

7. A display device comprising:
a base layer;
a display element layer on the base layer and comprising a plurality of light-emitting elements; and
a light control layer comprising a partitioning pattern on the display element layer, and a first light control part, a second light control part, and a third light control part which are separated by the partitioning pattern, the first light control part having a first quantum dot, the second light control part having a second quantum dot, and the third light control part not having any quantum dot,
wherein each of the light-emitting elements comprises
a first electrode,
a hole transport region on the first electrode,
a light-emitting layer on the hole transport region,
an electron transport region on the light-emitting layer, and
a second electrode on the electron transport region,
the second quantum dot comprising
a core having InP,
a first shell around the core, and comprising ZnTeSe,
a second shell around the first shell, and comprising ZnSe, and
a third shell around the second shell, and comprising ZnS,
a ratio of a number of moles of the Te in the first shell to a number of moles of the P in the core being about 0.02 to about 0.90.

8. The display device of claim 7, wherein the light-emitting layer is to emit a first light with a center wavelength of about 440 nm to about 460 nm.

9. The display device of claim 8, wherein the first quantum dot is to absorb the first light, and to emit a second light with a center wavelength of about 600 nm to about 640 nm,
the second quantum dot is to absorb light with a center wavelength of about 440 nm to about 460 nm, and to emit a third light with a center wavelength of about 510 nm to about 540 nm, and
the third light control part is to transmit the first light emitted from the light-emitting layer.

10. The display device of claim 9, further comprising a color filter layer on the light control layer, the color filter layer comprising:
a first filter part to transmit the second light, and overlapping the first light control part;
a second filter part to transmit the third light, and overlapping the second light control part; and
a third filter part to transmit the first light, and overlapping the third light control part.

11. The display device of claim 7, wherein the first shell is closer to the core than the second shell and the third shell.

12. The display device of claim 7, wherein a bandgap energy of the first shell is less than a bandgap energy of the second shell, and
a bandgap energy of the second shell is less than a bandgap energy of the third shell.

13. A display device having a first light-emitting region to emit a first light, a second light-emitting region to emit a second light, and a third light-emitting region to emit a third light, the display device comprising:
a base layer;
a first electrode on the base layer;
a hole transport region on the first electrode;
a light-emitting layer on the hole transport region, and to emit the third light;
an electron transport region on the light-emitting layer;
a second electrode on the electron transport region;
a first light control part in a region corresponding to the first light-emitting region on the second electrode, and comprising a first quantum dot to absorb the third light and to emit the first light;
a second light control part in a region corresponding to the second light-emitting region on the second electrode, and comprising a second quantum dot to absorb the third light and to emit the second light; and
a third light control part in a region corresponding to the third light-emitting region on the second electrode, and to transmit the third light,
wherein the second quantum dot comprises
a core having InP,
a first shell around the core, and having ZnTeSe,
a second shell around the first shell, and
a third shell around the second shell,
a ratio of a number of moles of the Te in the first shell to a number of moles of the P in the core being about 0.02 to about 0.90.

14. The display device of claim 13, wherein the third light has a center wavelength of about 440 nm to about 460 nm.

15. The display device of claim 14, wherein the first light has a center wavelength of about 600 nm to about 640 nm, and
the second light has a center wavelength of about 510 nm to about 540 nm.

16. The display device of claim 13, wherein the first shell is closer to the core than the second shell and the third shell.

17. The display device of claim 13, wherein a bandgap energy of the first shell is less than a bandgap energy of the second shell, and
a bandgap energy of the second shell is less than a bandgap energy of the third shell.

18. The display device of claim 13, wherein the second shell comprises ZnSe, and the third shell comprises ZnS.
